(19) United States
(12) Patent Application Publication
(10) Pub. No.: US 2008/0197415 A1
(43) Pub. Date: Aug. 21, 2008

(54) ELECTROSTATIC DISCHARGE PROTECTION CIRCUIT HAVING MULTIPLE DISCHARGE PATHS

(76) Inventor: Suk YUN, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/030,952

(22) Filed: Feb. 14, 2008

(30) Foreign Application Priority Data
Feb. 15, 2007 (KR) 10-2007-0016263

(51) Int. Cl. H01L 23/62; H02H 9/00

(52) U.S. Cl. 257/355; 361/56; 257/E29.217

(57) ABSTRACT

The present invention relates to an electrostatic discharge protection circuit of a semiconductor memory device to protect an internal circuit from static electricity. The electrostatic discharge protection circuit includes a first trigger unit which provides a first trigger voltage in response to static electricity transferred from at least one of a first and second voltage line. A second trigger unit provides a second trigger voltage by the static electricity in response to the first trigger voltage. An electrostatic discharge protection unit configures an electrostatic discharge path among the first voltage line, the second voltage line and an input/output pad in response the first and second trigger voltages. The electrostatic discharge speed of the electrostatic discharge protection unit is enhanced by the first and second trigger voltages.

### CROSS-REFERENCE TO RELATED APPLICATIONS

The present application claims priority to Korean patent application number 10-2007-0016263 filed on Feb. 15, 2007, which is incorporated herein by reference in its entirety.

### BACKGROUND OF THE INVENTION

The present invention relates generally to an electrostatic discharge protection circuit, and more particularly to an electrostatic discharge protection circuit of a semiconductor memory device to protect an internal circuit from static electricity.

In general, a MOS transistor is one of the devices typically used as an electrostatic discharge protection circuit. FIG. 1 shows a widely used structure for an electrostatic discharge protection circuit, where a PMOS transistor Pt is coupled between a power voltage line VDD and an input/output pad 10 and an NMOS transistor N1 is coupled between a ground voltage line VSS and the input/output pad 10.

As shown in FIG. 1, the gate of the NMOS transistor N1 and the gate of the PMOS transistor P1 are coupled to the ground voltage line VSS and the power voltage line VDD respectively, a channel is closed and therefore the NMOS transistor N1 and the PMOS transistor P1 do not operate when a memory chip operates normally.

However, when an electrostatic discharge occurs, a high voltage and current are flowing from the input/output pad 10. During an electrostatic discharge as described above, an avalanche breakdown occurs in a drain junction of the NMOS transistor N1 or a source junction of the PMOS transistor P1 and a result of the avalanche breakdown carriers are generated. The carriers then flow to a pick-up of the NMOS transistor N1 or the PMOS transistor P1 and raise an electric potential of the substrate, thereby inducing an operation of a diode between the substrate and the source or the substrate and the drain.

A series of such processes is referred to as a parasitic bipolar operation. The parasitic bipolar operation is performed only when an avalanche breakdown is occured, therefore the drain voltage of the NMOS transistor N1 or the source voltage of the PMOS P1 should be sufficiently increased until the avalanche breakdown occurs.

However, in the conventional electrostatic discharge protection circuit, which uses only the parasitic bipolar operation as shown in FIG. 1, problems arise as a result of decreasing size of the technology, for example decrease in a gate oxide thickness. The conventional electrostatic discharge protection circuit as shown in FIG. 1 cannot sufficiently protect the internal circuit 14 due to its limitation in operation speed.

In order to solve the problem of the operation speed, an electrostatic discharge protection circuit having a structure shown in FIG. 2 has been suggested.

Referring to FIG. 2, when static electricity is flowing from an input/output pad 10, a PMOS transistor P2, an NMOS transistor N2, and an NMOS transistor N3 (which is a power clamp device) are operated due to a voltage drop by resistors R1 and R2 and capacitors C1 and C2. The static electricity is discharged to respective voltage lines VDD and VSS according to the operation of the PMOS transistor P2, the NMOS transistor N2, and the NMOS transistor N3.

The conventional electrostatic discharge protection circuit of FIG. 2 operates faster as trigger voltages of respective MOS transistors P2, N2 and N3 are lowered, therefore, an internal circuit 14 can be effectively protected from the static electricity.

However, the resistors R1 and R2 and the capacitors C1 and C2 demand substantial surface area and as a result the total area of an electrostatic discharge protection circuit must be increased to accommodate the resistors R1 and R2 and the capacitors C1 and C2.

In order to reduce the area of an electrostatic discharge protection circuit, there has been suggested, as shown in FIG. 3, an electrostatic discharge protection circuit having a resistor R3, a capacitor C3, and a resistor R4, which are serially coupled between a power voltage line VDD and a ground voltage line VSS.

Specifically, due to a voltage drop by the resistor R3, the capacitor C3, and the resistor R4, which are serially coupled between a power voltage line VDD and a ground voltage line VSS, respective MOS transistors P3, N4 and N5 are operated to discharge static electricity to respective voltage lines VDD and VSS.

However, since the total series resistance of the resistor R3, the capacitor C3, and the resistor R4 is large, it is difficult for static current to flow in a gate of the respective MOS transistors P3, N4, and N5; and as a result electrostatic discharge performance may be diminished.

### SUMMARY OF THE INVENTION

Accordingly, the present invention provides an electrostatic discharge protection circuit in which an electrostatic discharge speed with respect to its area is superior.

The present invention provides an electrostatic discharge protection circuit in which a driving voltage of the electrostatic discharge protection circuit is lowered to enhance an electrostatic discharge speed.

Further present invention provides an electrostatic discharge protection circuit in which a resistance of a driving line providing a driving voltage of an electrostatic discharge protection device is properly controlled to enhance an electrostatic discharge performance.

According to an embodiment of the present invention, the electrostatic discharge protection circuit includes: a first trigger unit which provides a first trigger voltage in response to static electricity transferred from at least one of a first or second voltage line; a second trigger unit which provides a second trigger voltage by the static electricity in response to the first trigger voltage; and an electrostatic discharge protection unit which configures an electrostatic discharge path among the first voltage line, the second voltage line and an input/output pad in response to the first trigger voltage and the second trigger voltage.

Preferably, the first trigger unit provides the first trigger voltage corresponding to the potential drop by dropping an electric potential of the static electricity.

Preferably, the first trigger unit includes a capacitor and a resistor which are serially coupled between the first voltage line and the second voltage line, and the first trigger voltage is generated between the resistor and the capacitor.

Preferably, the second trigger unit provides the second trigger voltage corresponding to the potential drop by dropping an electric potential of the static electricity.

Preferably, the second trigger unit includes a resistor and a MOS transistor which are serially coupled between the first voltage line and the second voltage line, and the second trigger voltage is generated between the resistor and the MOS transistor as the first trigger voltage is inputted into a gate of the MOS transistor.

Preferably, the first MOS transistor is a NMOS transistor coupled between the resistor and the second voltage line.

Preferably, the electrostatic discharge protection unit includes a first MOS transistor which configures a first electrostatic discharge path between the input/output pad and the second voltage line in response to the first trigger voltage; and a second MOS transistor which configures a second electrostatic discharge path between the first voltage line and the input/output pad in response to the second trigger voltage.

Preferably, the first MOS transistor is a NMOS transistor coupled between the input/output pad and the second voltage line and inputted the first trigger voltage into a gate, and the second MOS transistor is a PMOS transistor coupled between the first voltage line and the input/output pad and inputted the second trigger voltage into a gate.

Preferably, the electrostatic discharge protection unit configures among the first voltage line, the second voltage line and the input/output pad by performing a parasitic bipolar operation according to the static electricity flowing from the input/output pad.

Preferably, the first voltage line is a power voltage line and the second voltage line is a ground voltage line.

According to another embodiment of the present invention, an electrostatic discharge protection circuit includes: a trigger unit which provides a trigger voltage in response to static electricity transferred from at least one of a first or second voltage line; a first discharge unit which drops an electric potential of the static electricity in response to the trigger voltage, and configures a first electrostatic discharge path between the first voltage line and an input/output pad by driving in response to the potential drop; and a second discharge unit which configures a second electrostatic discharge path between the input/output pad and the second voltage line by driving in response to the trigger voltage.

Preferably, the trigger unit provides the trigger voltage corresponding to the potential drop by dropping an electric potential of the static electricity.

Preferably, the trigger unit includes a capacitor and a resistor which are serially coupled between the first voltage line and the second voltage line, and the trigger voltage is generated between the resistor and the capacitor.

Preferably, the first discharge unit includes: a potential drop unit which provides a driving signal corresponding to the potential drop by dropping an electric potential of the static electricity in response to the trigger voltage; and a driving unit which configures the first electrostatic discharge path by driving in response to the driving signal.

Preferably, the potential drop unit includes a resistor and a MOS transistor which are serially coupled between the first voltage line and the second voltage line, and the driving signal is generated between the resistor and the MOS transistor as the trigger voltage is inputted into a gate of the MOS transistor.

Preferably, the driving unit is a MOS transistor coupled between the first voltage line and the input/output pad and inputted the driving signal into a gate.

Preferably, the second discharge unit is a MOS transistor coupled between the input/output pad and the second voltage line and inputted the trigger voltage into a gate.

Preferably, the first and second discharge units configure the first and second electrostatic discharge paths by performing respective parasitic bipolar operations according to the static electricity flowing from the input/output pad.

Preferably, the first voltage line is a power voltage line and the second voltage line is a ground voltage line.

### BRIEF DESCRIPTION OF THE DRAWINGS

FIG. 1 is a circuit diagram illustrating an example of a conventional electrostatic discharge protection circuit.

FIG. 2 is a circuit diagram illustrating another example of a conventional electrostatic discharge protection circuit.

FIG. 3 is a circuit diagram illustrating another example of a conventional electrostatic discharge protection circuit.

FIG. 4 is a circuit diagram illustrating an electrostatic discharge protection circuit according to an embodiment of the present invention.

FIG. 5 is a waveform diagram in which operation properties of a PMOS transistor P1 in FIG. 1 and a PMOS transistor P4 in FIG. 4 are snapback simulated.

### DESCRIPTION OF SPECIFIC EMBODIMENTS

Hereinafter, preferred embodiments of the present invention will be described in detail with reference to the accompanying drawings.

In an electrostatic discharge protection circuit of the present invention, a trigger circuit using a gate coupled MOS (GCMOS) transistor is coupled to the gate of a main electrostatic discharge protection device to apply a bias, thereby lowering the operation voltage of the main electrostatic discharge protection device.

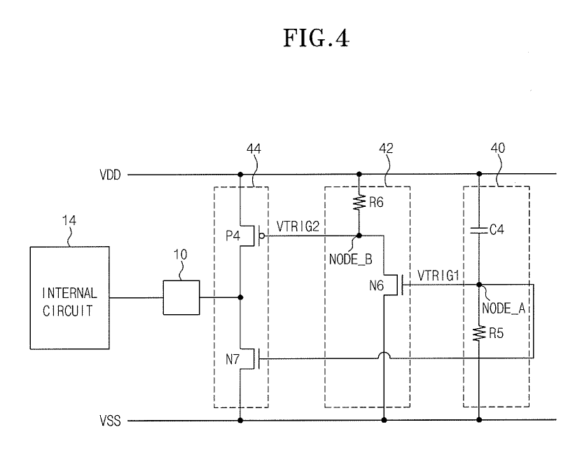

Specifically, referring to FIG. 4, an electrostatic discharge protection circuit of the present invention includes a trigger unit 40, a trigger unit 42, and an electrostatic discharge protection unit 44.

The trigger unit 40 provides a trigger voltage VTRIG1 to a node NODE₁₃ A in response to static electricity transferred from at least one of a power voltage line VDD and a ground voltage line VSS. For example, a potential drop occurs when static electricity is transferred from at least one of a power voltage line VDD and a ground voltage line VSS, and the trigger voltage VTRIG1 corresponding to the potential drop may be provided to the node NODE₁₃ A.

The trigger unit 40, which provides the trigger voltage VTRIG1, may include a capacitor C4, coupled between the power voltage line VDD and the node NODE₁₃ A, and a resistor R5, coupled between the node NODE₁₃ A and the ground voltage line Vss.

The trigger unit 42 configures a trigger voltage VTRIG2 according to static electricity transferred from at least one of a power voltage line VDD and a ground voltage line VSS, and the trigger unit 42 provides the trigger voltage VTRIG2 to a node NODE₁₃ B in response to the trigger voltage VTRIG1. For example, a potential drop occurs according to static electricity transferred from at least one of a power voltage line VDD and a ground voltage line VSS in response to the trigger voltage TRIG1, and the trigger voltage VTRIG2 corresponding to the potential drop may be provided.

The trigger unit 42, which provides the trigger voltage VTRIG2 in response to the trigger voltage VTRIG1, may include a resistor R6, coupled between the power voltage line VDD and the node NODE₁₃ B, and a gate coupled NMOS transistor N6, coupled between the node NODE₁₃ B and the ground voltage line VSS. Herein, the gate of the NMOS transistor N6 is coupled to the node NODE₁₃ A.

The electrostatic discharge protection unit 44 configures an electrostatic discharge path among the power voltage line VDD, the ground voltage line VSS and the input/output pad 10 in response to the trigger voltage VTRIG1 and the trigger voltage VTRIG2.

The electrostatic discharge protection unit 44, which configures the electrostatic discharge path in response to the trigger voltage VTRIG1 and the trigger voltage VTRIG2, may include a PMOS transistor P4 coupled between the power voltage line VDD and the input/output pad 10 and an NMOS transistor N7 coupled between the input/output pad 10 and the ground voltage line VSS. Herein, the gate of the PMOS transistor P4 is coupled to the node NODE₁₃ B and the gate of the NMOS transistor N7 is coupled to the node NODE₁₃ A.

The electrostatic discharge protection unit 44 may provide the electrostatic discharge path among the power voltage line VDD, the ground voltage line VSS and input/output pad 10 by performing a parasitic bipolar operation according to the static electricity flowing from the input/output pad 10.

The electrostatic discharge protection circuit of the present invention, according to another embodiment of the present invention, may include a trigger unit, a first discharge unit and a second discharge unit.

The trigger unit provides the trigger voltage in response to the static electricity transferred from at least one of the power voltage line VDD and the ground voltage line VSS. For example, it may have a structure identical to the trigger unit 40. Herein, the trigger voltage may correspond to the trigger voltage VTRIG1.

The first discharge unit drops an electric potential of the static electricity in response to the trigger voltage VTRIG1, and configures a first electrostatic discharge path between the power voltage line VDD and the input/output pad 10 by driving in response to the potential drop.

The first discharge unit may include a potential drop unit that provides a driving signal corresponding to the potential drop by dropping an electric potential of the static electricity in response to the trigger voltage VTRIG1. The first discharge unit may further include a driving unit which configures the first electrostatic discharge path by driving in response to the driving signal.

The potential drop unit may have the identical structure with the trigger unit 42, and the driving unit may include the PMOS transistor P4. The driving signal may correspond to the trigger voltage VTRIG2.

The second discharge unit 2 configures a second electrostatic discharge path between the input/output pad 10 and the general voltage line VSS by driving in response to the trigger voltage VTRIG1. For example, the NMOS transistor N7 may be included. The electrostatic discharge protection circuit having the above described structure discharges the static electricity through various paths. Hereinafter, some representative cases are provided. The first representative case provided is the discharging of a positive static electricity flowing from the input/output pad 10 to the ground voltage line VSS. The second representative case provided is the discharging of a negative static electricity flowing from the input/output pad 10 to the power voltage line VDD. These representative cases are explained in detail below.

In the first representative case, the positive static electricity flowing from the input/output pad 10 is discharged to the ground voltage line VSS, electrostatic current raises an electric potential of the node NODE₁₃ A i.e., a level of the trigger voltage VTRIG1 while passing through the PMOS transistor P4, the capacitor C4 and the resistor R5.

When the level of the trigger voltage VTRIG1 is raised, the NMOS transistor N7 is turned on to configure a current path between the input/output pad 10 and the ground voltage line VSS and the electrostatic current flowing from the input/output pad 10 is therefore discharged to the ground voltage line VSS.

At this time, since the NMOS transistor N7 does not perform a parasitic bipolar operation but is turned on by the trigger voltage VTRIG1, an electrostatic discharge speed can be accelerated.

In the second representative case, the negative static electricity flowing from the input/output pad 10 is discharged to the power voltage line VDD, electrostatic current raises an electric potential of the node NODE₁₃ A i.e. a level of the trigger voltage VTRIG1 while passing through the PMOS transistor P4, the capacitor C4 and the resistor R5.

When the level of the trigger voltage VTRIG1 is raised, the NMOS transistor N6 is turned on to configure a current path between the node NODE₁₃ B and the ground voltage line VSS and an electric potential of the node NODE₁₃ B i.e., a level of the trigger voltage VTRIG2, is gradually lowered as the current path is configured.

When an electric potential between the trigger voltage VTRIG2 and the source of the PMOS transistor P4 exceeds to a threshold voltage, the PMOS transistor P4 is turned on to configure a current path between the input/output pad 10 and the power voltage line VDD and the electrostatic current flowing from the input/output pad 10 is therefore discharged to the power voltage line VDD.

At this time, as similarly shown in the first case, since the PMOS transistor P4 does not perform a parasitic bipolar operation but is turned on by the trigger voltage VTRIG2, the electrostatic discharge speed can be accelerated.

As described above, the electrostatic discharge protection circuit lowers an operation voltage of a main electrostatic discharge protection device i.e., the PMOS transistor P4, using the NMOS transistor N6 coupled between the node NODE₁₃ B and the ground voltage line and has therefore enhances the electrostatic discharge speed.

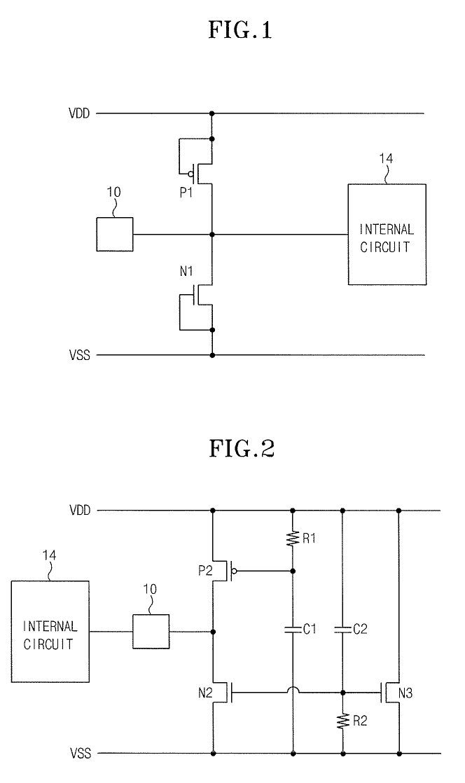

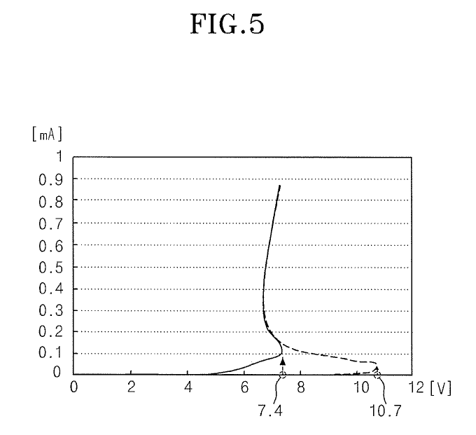

FIG. 5 shows a comparison of properties of the PMOS transistor P1 of the conventional electrostatic discharge protection circuit of FIG. 1 and the PMOS transistor P4 of the electrostatic discharge protection circuit of the present invention in FIG. 4. More specifically, the trigger voltage of the PMOS transistor P1 of the conventional electrostatic discharge protection circuit of FIG. 1 is about 10.7V as shown by a dotted line in FIG. 5 while the trigger voltage of the PMOS transistor P4 of the electrostatic discharge protection circuit of the present invention is about 7.4V as shown by a solid line in FIG. 5 and lowered by about 3.3V. In other words, it can be appreciated that the PMOS transistor P4 of the electrostatic discharge protection circuit of the present invention operates faster than the PMOS transistor P1 of the conventional electrostatic discharge protection circuit.

The electrostatic discharge protection circuit of the present invention also can lower driving voltages of the main electrostatic discharge protection device P4 and N7 to enhance the operation speed without occupying a smaller area as compared to the conventional electrostatic discharge protection circuit shown in FIG. 2. In other words, the electrostatic discharge protection circuit of the present invention offers superior electrostatic discharge speed with respect to its area.

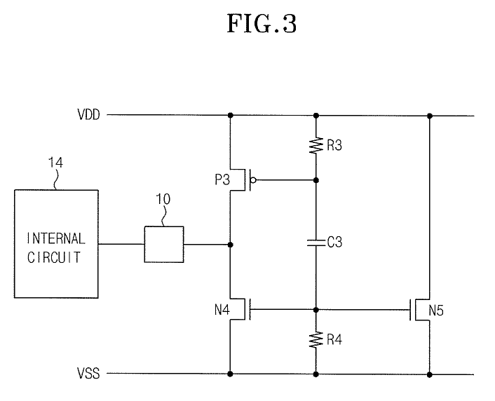

In addition, resistances of the node NODE₁₃ A, which provides the trigger voltage VTRIG1 to the gate of the NMOS transistor N7, and the node NODE₁₃ B, which provides the trigger voltage VTRIG2 to the gate of the PMOS transistor P4, are not as large as resistances in the electrostatic discharge protection circuit shown in FIG. 3. Therefore the PMOS transistor P4 and the NMOS transistor N7 operate quickly when the static electricity is generated, which further enhances the electrostatic discharge performance of the electrostatic discharge protection circuit.

As is apparent from the above description, the present invention offers superior electrostatic discharge speed with respect to its area because a trigger circuit using a gate coupled MOS transistor is coupled to a gate of a main electrostatic discharge protection device i.e., a MOS transistor to apply a bias.

Also, the present invention enhances electrostatic discharge speed because the driving voltage of the main electrostatic discharge protection device is lowered using the trigger circuit of the present invention.

In addition, the present invention enhances electrostatic discharge performance because the resistance through which the trigger voltage is provided to the main electrostatic discharge protection device has been properly controlled.

Those skilled in the art will appreciate that the specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended claims.

What is claimed is:

1. An electrostatic discharge protection circuit, comprising:
a first trigger unit providing a first trigger voltage in response to static electricity transferred from at least one of a first and second voltage line;
a second trigger unit providing a second trigger voltage by the static electricity in response to the first trigger voltage; and
an electrostatic discharge protection unit which configures an electrostatic discharge path for discharging the static electricity, the electrostatic discharge path being configured among the first voltage line, the second voltage line, and an input/output pad in response to the first trigger voltage and the second trigger voltage.

2. The electrostatic discharge protection circuit as set forth in claim 1, wherein the first trigger unit provides the first trigger voltage corresponding to a potential drop by dropping an electric potential of the static electricity.

3. The electrostatic discharge protection circuit as set forth in claim 2, wherein the first trigger unit comprises a capacitor and a resistor, the capacitor and the resistor serially coupled between the first voltage line and the second voltage line, and
wherein the first trigger voltage is generated at a first node between the resistor and the capacitor.

4. The electrostatic discharge protection circuit as set forth in claim 1, wherein the second trigger unit provides the second trigger voltage corresponding to a potential drop by dropping an electric potential of the static electricity in response to the first trigger voltage.

5. The electrostatic discharge protection circuit as set forth in claim 4, wherein the second trigger unit includes a resistor and a MOS transistor, the resistor and the MOS transistor serially coupled between the first voltage line and the second voltage line, and
wherein the gate of the MOS transistor receives the first trigger voltage, and the second trigger voltage is generated at a second node between the resistor and the MOS transistor.

6. The electrostatic discharge protection circuit as set forth in claim 5, wherein the MOS transistor is a NMOS transistor coupled between the resistor and the second voltage line.

7. The electrostatic discharge protection circuit as set forth in claim 1, wherein the electrostatic discharge protection unit comprises:
a first MOS transistor which configures a first electrostatic discharge path between the input/output pad and the second voltage line in response to the first trigger voltage; and
a second MOS transistor which configures a second electrostatic discharge path between the first voltage line and the input/output pad in response to the second trigger voltage.

8. The electrostatic discharge protection circuit as set forth in claim 7, wherein the first MOS transistor is a NMOS transistor coupled between the input/output pad and the second voltage line and a gate of the first MOS transistor receives the first trigger voltage.

9. The electrostatic discharge protection circuit as set forth in claim 7, wherein the second MOS transistor is a PMOS transistor coupled between the first voltage line and the input/output pad and a gate of the second MOS transistor receives the second trigger voltage.

10. The electrostatic discharge protection circuit as set forth in claim 1, wherein the electrostatic discharge protection unit configures the electrostatic discharge path among the first voltage line, the second voltage line, and the input/output pad by performing a parasitic bipolar operation according to the static electricity flowing from the input/output pad to the electrostatic discharge protection unit.

11. The electrostatic discharge protection circuit as set forth in claim 1, wherein the first voltage line is a power voltage line and the second voltage line is a ground voltage line.

12. An electrostatic discharge protection circuit, comprising:
a trigger unit providing a trigger voltage in response to static electricity transferred from at least one of a first and second voltage line;
a first discharge unit which drops an electric potential of the static electricity in response to the trigger voltage, and configures a first electrostatic discharge path between the first voltage line and an input/output pad by driving in response to a potential drop; and
a second discharge unit which configures a second electrostatic discharge path between the input/output pad and the second voltage line by driving in response to the trigger voltage.

13. The electrostatic discharge protection circuit as set forth in claim 12, wherein the trigger unit provides the trigger voltage corresponding to the potential drop by dropping an electric potential of the static electricity.

14. The electrostatic discharge protection circuit as set forth in claim 13, wherein the trigger unit comprises a capacitor and a resistor, the capacitor and the resistor serially coupled between the first voltage line and the second voltage line, and
wherein the trigger voltage is generated at a first node between the resistor and the capacitor.

15. The electrostatic discharge protection circuit as set forth in claim 12, wherein the first discharge unit comprises:
a potential drop unit which provides a driving signal corresponding to the potential drop by dropping an electric potential of the static electricity in response to the trigger voltage; and
a driving unit which configures the first electrostatic discharge path by driving in response to the driving signal.

16. The electrostatic discharge protection circuit as set forth in claim 15, wherein the potential drop unit includes a resistor and a MOS transistor which are serially coupled between the first voltage line and the second voltage line, and the driving signal is generated at a second node between the resistor and the MOS transistor as the trigger voltage is inputted into a gate of the MOS transistor.

17. The electrostatic discharge protection circuit as set forth in claim 15, wherein the driving unit is a MOS transistor coupled between the first voltage line and the input/output pad and a gate of the MOS transistor of the driving unit receives the driving signal.

18. The electrostatic discharge protection circuit as set forth in claim 12, wherein the second discharge unit is a MOS transistor coupled between the input/output pad and the second voltage line and the gate of the MOS of the second discharge unit receives the trigger voltage.

19. The electrostatic discharge protection circuit as set forth in claim 12, wherein the first and second discharge units configure the first and second electrostatic discharge paths by performing respective parasitic bipolar operations according to the static electricity flowing from the input/output pad to the second discharge unit.

20. The electrostatic discharge protection circuit as set forth in claim 12, wherein the first voltage line is a power voltage line and the second voltage line is a ground voltage line.
